(19) United States
(12) Patent Application Publication
(10) Pub. No.: US 2025/0132547 A1
(43) Pub. Date: Apr. 24, 2025

(54) CABLE PASSTHROUGH INTERLOCK CABINET

(71) Applicant: STEWART & STEVENSON LLC, Houston, TX (US)

(72) Inventors: Harrison SMITH, Houston, TX (US); David MORGAN, Houston, TX (US)

(21) Appl. No.: 18/906,780

(22) Filed: Oct. 4, 2024

Related U.S. Application Data
(60) Provisional application No. 63/545,270, filed on Oct. 23, 2023.

(51) Int. Cl. H02G 3/30; B01F 23/50; B01F 33/502; B01F 35/60; B01F 101/49; E21B 43/26; H05K 5/02

(52) U.S. Cl. CPC H02G 3/24; B01F 23/59; B01F 33/5026; B01F 35/60; H05K 5/0208; H05K 5/0221; H05K 5/0247; B01F 2101/49; E21B 43/2607

(57) ABSTRACT

A blender system may include a skid and a blender assembly, the blender assembly including a blender tub. Further, the blender system may include a cable passthrough interlock cabinet. The cable passthrough interlock cabinet includes a first articulating access panel, the articulating access panel having a panel plate and cable notches cut or formed into the panel plate. The cable passthrough interlock cabinet also includes an enclosure, the enclosure connected to the articulating access panel, the enclosure having a face and an interior, with cable holes in the interior and a latch, the latch disposed on the articulating access panel. Also, the cable passthrough interlock cabinet may include a strike plate, the strike plate positioned on the face of the enclosure, the strike plate corresponding to the latch.

### CROSS-REFERENCE TO RELATED APPLICATIONS

This application is a nonprovisional application which claims priority from U.S. provisional application No. 63/545,270, filed Oct. 23, 2023, which is incorporated by reference herein in its entirety.

### TECHNICAL FIELD/FIELD OF THE DISCLOSURE

The present disclosure relates generally to well service equipment and specifically to equipment used with well fluids.

### BACKGROUND OF THE DISCLOSURE

During drilling, completion, and production operations, fluids are circulated through a wellbore. Various chemicals are introduced into the fluids, referred to herein as the slurry, to produce slurry having desirable characteristics. In some cases, chemicals may be provided in dry form.

### SUMMARY

A blender system is disclosed. The blender system may include a skid and a blender assembly, the blender assembly including a blender tub. Further, the blender system may include a cable passthrough interlock cabinet. The cable passthrough interlock cabinet includes a first articulating access panel, the articulating access panel having a panel plate and cable notches cut or formed into the panel plate. The cable passthrough interlock cabinet also includes an enclosure, the enclosure connected to the articulating access panel, the enclosure having a face and an interior, with cable holes in the interior and a latch, the latch disposed on the articulating access panel. Also, the cable passthrough interlock cabinet may include a strike plate, the strike plate positioned on the face of the enclosure, the strike plate corresponding to the latch.

A method for securing electrical cables for a blender system is disclosed. The method may include supplying a blender assembly, the blender assembly including a blender tub and supplying a cable passthrough interlock cabinet. The cable passthrough interlock cabinet may include a first articulating access panel, the articulating access panel having a panel plate and cable notches cut or formed into the panel plate, the access panel in an open position and an enclosure, the enclosure connected to the articulating access panel, the enclosure having a face and an interior, with cable holes in the interior. In addition, the cable passthrough interlock cabinet may include a latch, the latch disposed on the articulating access panel and a captive key, the key positioned within the latch. Also, the cable passthrough interlock cabinet may include a strike plate, the strike plate positioned on the face of the enclosure, the strike plate corresponding to the latch. The method further includes inserting cabling through the cable holes and moving the articulating access panel to a closed position to enclose the cabling through the cable notches. The method also includes forming a mechanical interlock between the articulating access panel and the enclosure.

### BRIEF DESCRIPTION OF THE DRAWINGS

The present disclosure is best understood from the following detailed description when read with the accompanying figures. It is emphasized that, in accordance with the standard practice in the industry, various features are not drawn to scale. In fact, the dimensions of the various features may be arbitrarily increased or reduced for clarity of discussion.

FIG. 1a depicts a perspective view of a blender system consistent with at least one embodiment of the present disclosure.

FIG. 1b depicts an expanded view of the cable passthrough interlock cabinet of the blender system of claim 1 consistent with certain embodiments of the present disclosure.

FIG. 2 depicts a perspective view of the cable passthrough interlock cabinet.

FIG. 3 is an alternate perspective view of the cable passthrough interlock cabinet of FIG. 2.

FIG. 4 is a side view of the cable passthrough interlock cabinet consistent with certain embodiments of the present disclosure.

FIG. 5 is a perspective view of the cable passthrough interlock cabinet with the articulating access panel closed and cables positioned therein consistent with certain embodiments of the present disclosure.

FIG. 6 is a perspective view of the cable passthrough interlock cabinet with the articulating access panel open and cables shown with cable interface consistent with certain embodiments of the present disclosure.

FIG. 7 is a front view of a power cabinet consistent with certain embodiments of the present disclosure.

### DETAILED DESCRIPTION

It is to be understood that the following disclosure provides many different embodiments, or examples, for implementing different features of various embodiments. Specific examples of components and arrangements are described below to simplify the present disclosure. These are, of course, merely examples and are not intended to be limiting. In addition, the present disclosure may repeat reference numerals and/or letters in the various examples. This repetition is for the purpose of simplicity and clarity and does not in itself dictate a relationship between the various embodiments and/or configurations discussed.

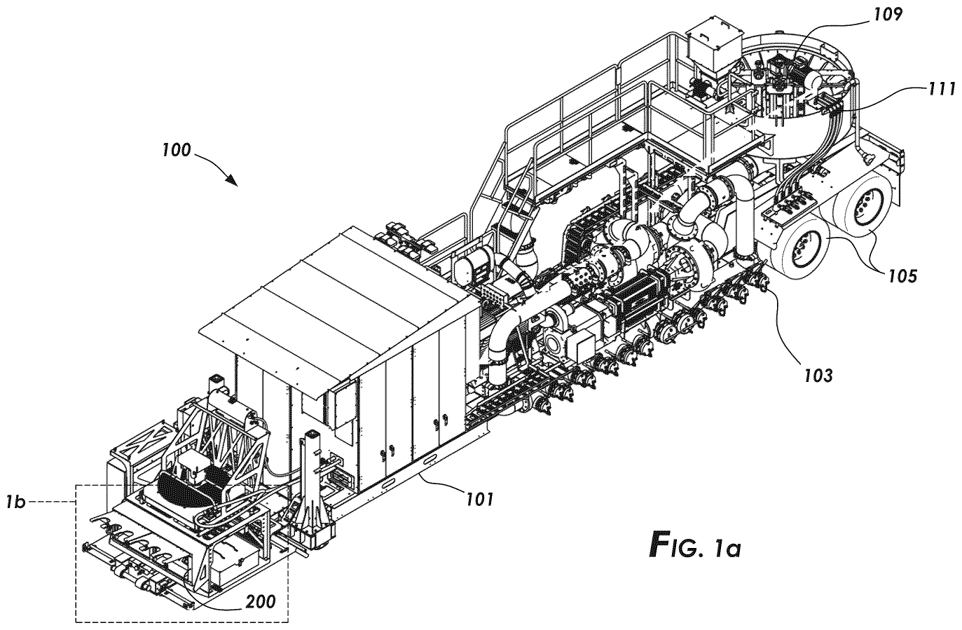

FIG. 1a depicts blender system 100. Blender system 100 may be used to prepare fluids for use in wellbore operations including stimulation operations such as hydraulic fracturing operation. For the purposes of this disclosure and without any intent to limit the scope of this disclosure, the fluids prepared by integrated blender system 100 are referred to herein as a slurry made up of ingredients, chemicals, products, and base fluids as understood in the art such as, for example and without limitation, friction reducer, high viscosity friction reducer, guar or synthetic gel, inhibitors, PH buffers, and biocides.

In some embodiments, blender system 100 may include skid 101. Skid 101 may support components of blender system 100 and may provide for transportation of blender system 100 while allowing all components thereof to remain operatively coupled. In some embodiments, skid 101 may be positioned on or may be part of trailer 103 that includes one or more wheels 105. In some such embodiments, trailer 103 may be a rockover trailer.

Blender system 100 may include blender assembly 109. Blender assembly 109 may be adapted to mix one or more ingredients, chemicals, and products with a base fluid to generate a slurry used, for example and without limitation, in a wellbore stimulation operation such as a hydraulic fracturing operation. Blender assembly 109 may include blender tub 111.

Blender assembly 109, along with other supporting electrical systems for blender system 100 on skid 101, may use electrical power supplied from sources aside from those located on skid 101. To accommodate this outside power, blender system 100 may include cable passthrough interlock cabinet 200, shown in the open position in FIGS. 1a and 1b. Cable passthrough interlock cabinet 200 may enclose, access, and direct cables from outside power sources. Cable passthrough interlock cabinet 200 may also function as an interlock safety mechanism for electrical power being transmitted to blender assembly 109.

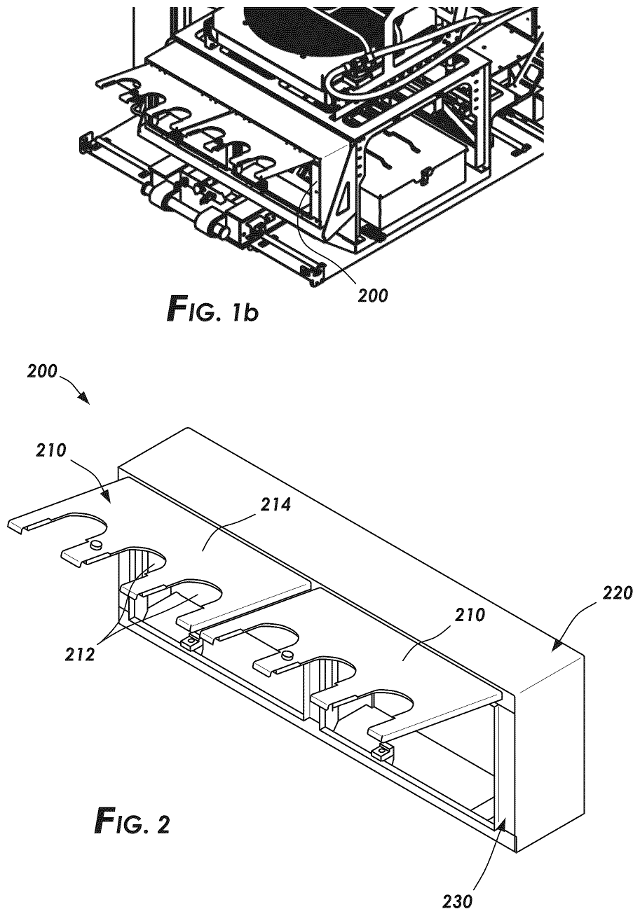

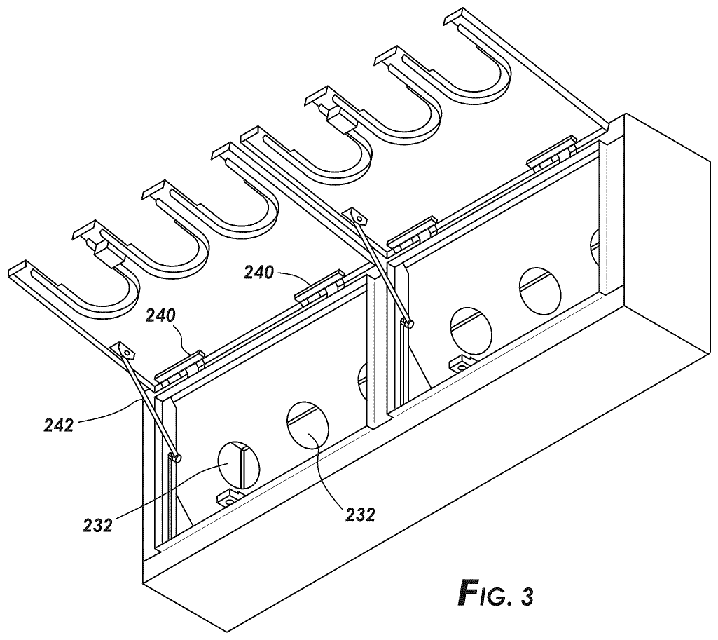

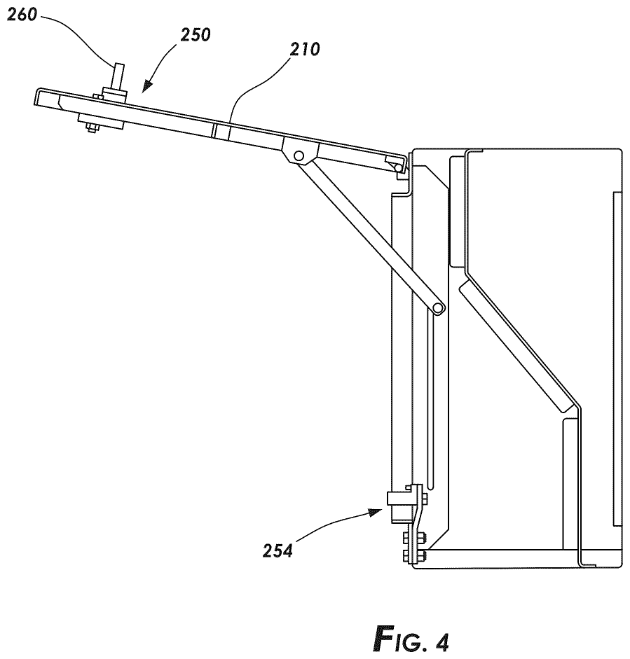

FIG. 2 shows cable passthrough interlock cabinet 200 having articulating access panel 210 with articulating access panel 210 being open in FIG. 2. Cable passthrough interlock cabinet 200 further includes enclosure 220 and face 230 of enclosure 220. As shown in FIG. 3, articulating access panel 210 includes hinges 240 which serve to connect articulating access panel 210 with enclosure 220. In certain embodiments, support arm 242 may also connect articulating access panel 210 with enclosure 220. Further, as shown in FIGS. 2 and 3, in certain embodiments, cable passthrough interlock cabinet 200 may include a plurality of articulating access panels 210 connected to enclosure 220. When a plurality of articulating access panels 210 are present, the plurality of articulating access panels 210 may operate independently or together in opening and closing.

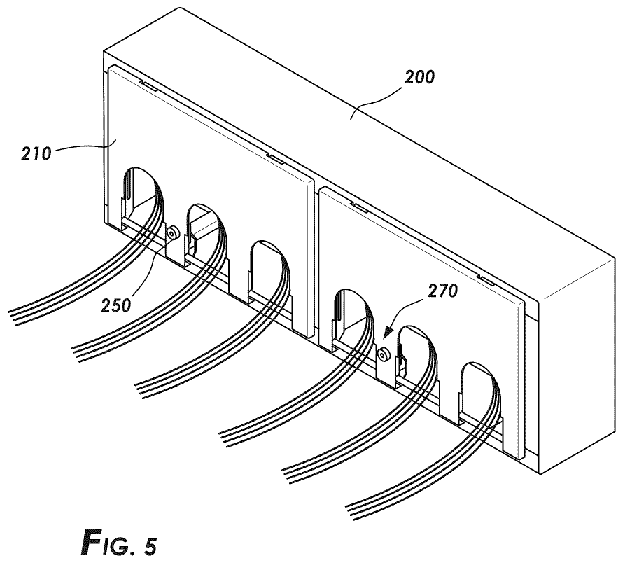

With additional attention to FIGS. 2 and 3, articulating access panel 210 may include a plurality of cable notches 212. Cable notches 212 may be formed or cut into panel plate 214. When articulating access panel 210 is closed, cable notches 212 may align with cable holes 232 in enclosure 220. Thus, as shown in FIG. 5, when articulating access panel 210 is closed, cables 400 may pass through cable notches 212 and through cable holes 232 to electrical distribution equipment, such as a switchgear.

Articulating access panel 210 includes latch 250. During certain times of the operation of cable passthrough interlock cabinet 200, captive key 260 may be engaged with latch 250. Further, face 230 of enclosure 220 may include strike plate 254 positioned thereon and corresponding to latch 250 forming interlock 270 as shown in FIG. 5. Once interlock 270 has been formed by engaging latch 250 with strike plate 254, captive key 260 may be removed from latch 250, thereby locking cable passthrough interlock cabinet 200. Inclusion of a mechanical interlock 270 may restrict or prevent disconnection of articulating access panel 210 without reinsertion of captive key 260. Thus, when articulating access panel 210 is closed, interlock 270 is formed. Articulating access panel 210, while closed and locked via captive key 260 and interlock 270, allows for the interlocking and enclosed routing of a plurality of cable array using a single key.

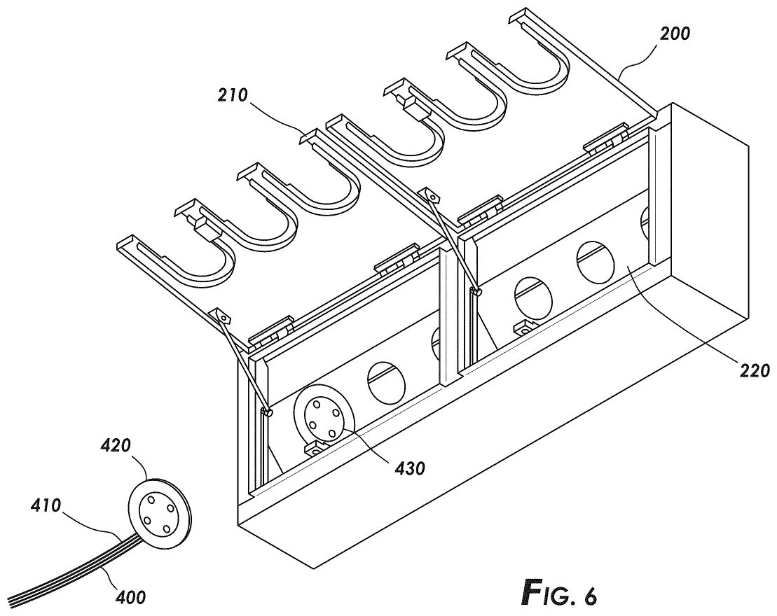

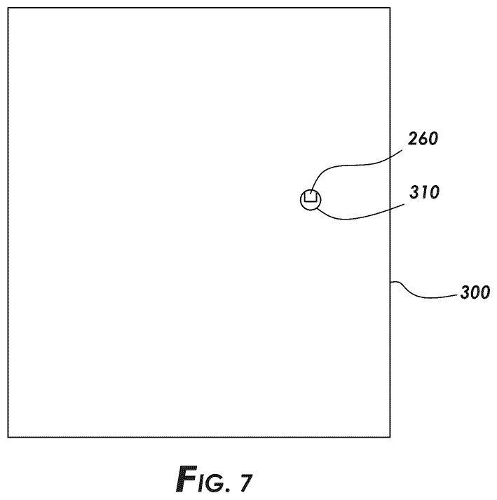

As shown in FIG. 6, cables 400 may be combined into array 410, using connector 420, to each other and subsequently to the cable passthrough interlock cabinet 200 through receptacles 430, as shown in FIG. 6. Captive key 260 may also be used in lock 310 for power cabinet 300 to which the cables are connected and located on skid 101, as shown in FIG. 7. With removal of captive key 260, access is prevented or restricted to the interior of cable passthrough interlock cabinet 200. With removal of captive key 260 from power cabinet 300, electrical power to the cabling routed through the cable passthrough interlock cabinet 200 is stopped. Access to power cabinet 300 is restricted until articulating access panel 210 is closed and retarded from opening; access to cable passthrough interlock cabinet 200 is restricted unless power cabinet 300 is closed and retarded from opening.

The foregoing outlines features of several embodiments so that a person of ordinary skill in the art may better understand the aspects of the present disclosure. Such features may be replaced by any one of numerous equivalent alternatives, only some of which are disclosed herein. One of ordinary skill in the art should appreciate that they may readily use the present disclosure as a basis for designing or modifying other processes and structures for carrying out the same purposes and/or achieving the same advantages of the embodiments introduced herein. One of ordinary skill in the art should also realize that such equivalent constructions do not depart from the spirit and scope of the present disclosure and that they may make various changes, substitutions, and alterations herein without departing from the spirit and scope of the present disclosure.

1. A blender system comprising:
a skid;
a blender assembly, the blender assembly including a blender tub; and
a cable passthrough interlock cabinet, the cable passthrough interlock cabinet having:
a first articulating access panel, the articulating access panel having a panel plate and cable notches cut or formed into the panel plate;
an enclosure, the enclosure connected to the articulating access panel, the enclosure having a face and an interior, with cable holes in the interior;
a latch, the latch disposed on the articulating access panel; and
a strike plate, the strike plate positioned on the face of the enclosure, the strike plate corresponding to the latch.

2. The blender system of claim 1 further comprising a captive key, the captive key positioned within the latch.

3. The blender system of claim 1 further comprising a second articulating access panel, the second articulating access panel having a second panel plate and second cable notches cut or formed into the second panel plate.

4. The blender system of claim 1, wherein the first articulating access panel is connected to the enclosure via a hinge.

5. The blender system of 1, wherein the first articulating access panel is connected to the enclosure via a support arm.

6. The blender system of claim 1, wherein the skid is positioned on or as part of a trailer.

7. The blender system of claim 6, wherein the trailer is a rockover trailer.

8. The blender system of claim 1 further comprising cables, the cables positioned within the cable notches.

9. The blender system of claim 8, wherein the cables pass through the cable holes.

10. The blender system of claim 8, wherein the cables are formed into an array.

11. The blender system of claim 10, wherein the cables are formed into an array with a connector.

12. The blender system of claim 8 further comprising a power cabinet, the power cabinet connected to the cable passthrough interlock cabinet by the cables.

13. A method for securing electrical cables for a blender system comprising:
supplying a blender assembly, the blender assembly including a blender tub;
supplying a cable passthrough interlock cabinet, the cable passthrough interlock cabinet having:
a first articulating access panel, the articulating access panel having a panel plate and cable notches cut or formed into the panel plate, the access panel in an open position;
an enclosure, the enclosure connected to the articulating access panel, the enclosure having a face and an interior, with cable holes in the interior;
a latch, the latch disposed on the articulating access panel;
a captive key, the key positioned within the latch; and
a strike plate, the strike plate positioned on the face of the enclosure, the strike plate corresponding to the latch;
inserting cabling through the cable holes;
moving the articulating access panel to a closed position to enclose the cabling through the cable notches; and
forming a mechanical interlock between the articulating access panel and the enclosure.

14. The method of claim 13 wherein the step of forming an interlock further comprises:
engaging the latch with the strike plate; and
removing the captive key from the latch.

15. The method of claim 14 further comprising supplying a power cabinet.

16. The method of claim 15 further comprising opening the power cabinet with the captive key.

17. The method of claim 14 further comprising forming the cables into an array.

18. The method of claim 17, wherein the cables are formed into an array using a connector.

19. The method of claim 14, wherein the captive key is a single key.

20. The method of claim 14, wherein the captive key cannot be removed from the latch until the articulating access panel is moved to a closed position.
